(19) United States
(12) Patent Application Publication
(10) Pub. No.: US 2023/0051382 A1
(43) Pub. Date: Feb. 16, 2023

(54) SEMICONDUCTOR MEMORY DEVICE AND METHOD OF MANUFACTURING SEMICONDUCTOR MEMORY DEVICE

(71) Applicant: Kioxia Corporation, Tokyo (JP)

(72) Inventor: Koichi YAMAMOTO, Yokkaichi Mie (JP)

(73) Assignee: Kioxia Corporation, Tokyo (JP)

(21) Appl. No.: 17/547,567

(22) Filed: Dec. 10, 2021

(30) Foreign Application Priority Data
Aug. 16, 2021 (JP) 2021-132297

(51) Int. Cl. H01L 23/535; H01L 27/11556; H01L 27/11582; H01L 21/768

(52) U.S. Cl. CPC H01L 23/535; H01L 27/11556; H01L 27/11582; H01L 21/76805; H01L 21/76895

(57) ABSTRACT

A semiconductor memory device according to an embodiment includes: a stacked body in which a plurality of first conductive layers and a plurality of first insulating layers are alternately stacked one by one and includes a stepped portion in which, a first pillar disposed in the stepped portion, the first pillar extending in a stacking direction of the stacked body; and a second pillar extending in the stacking direction within the stacked body, the second pillar forming a memory cell at each intersection with at least a part of the plurality of first conductive layers. The first pillar has a semiconductor layer or a second conductive layer extending in the stacking direction and serving as a core material of the first pillar, and a second insulating layer covering a side wall of the semiconductor layer or the second conductive layer and serving as a liner layer of the first pillar.

### CROSS-REFERENCE TO RELATED APPLICATIONS

This application is based upon and claims the benefit of priority from Japanese Patent Application No. 2021-132297, filed on Aug. 16, 2021; the entire contents of which are incorporated herein by reference.

### FIELD

Embodiments described herein relate generally to a semiconductor memory device and a method of manufacturing the semiconductor memory device.

### BACKGROUND

In a semiconductor memory device such as a three-dimensional nonvolatile memory, a plurality of memory cells is three-dimensionally disposed within a stacked body in which a plurality of conductive layers is stacked. The plurality of conductive layers is processed in a stepped manner, for example, and a plurality of contacts is each connected to the conductive layers. In the stacked body, for example, pillars for supporting the stacked body are disposed. If these contacts come into contact with the pillars, a short circuit failure may occur in the contact, for example.

### BRIEF DESCRIPTION OF THE DRAWINGS

FIGS. 1A to 1D are views illustrating an example of the configuration of a semiconductor memory device according to a first embodiment;

FIGS. 2A to 2C are cross-sectional views illustrating an example of a procedure of a method of manufacturing the semiconductor memory device according to the first embodiment;

FIGS. 3A to 3C are cross-sectional views illustrating an example of the procedure of the method of manufacturing the semiconductor memory device according to the first embodiment;

FIGS. 4A to 4C are cross-sectional views illustrating an example of the procedure of the method of manufacturing the semiconductor memory device according to the first embodiment;

FIGS. 5A to 5C are cross-sectional views illustrating an example of the procedure of the method of manufacturing the semiconductor memory device according to the first embodiment;

FIGS. 6A to 6C are cross-sectional views illustrating an example of the procedure of the method of manufacturing the semiconductor memory device according to the first embodiment;

FIGS. 7A and 7B are cross-sectional views illustrating an example of the procedure of the method of manufacturing the semiconductor memory device according to the first embodiment;

FIGS. 8A to 8C are cross-sectional views illustrating an example of the procedure of the method of manufacturing the semiconductor memory device according to the first embodiment;

FIGS. 9A to 9E are cross-sectional views illustrating an example of the procedure of the method of manufacturing the semiconductor memory device according to the first embodiment;

FIGS. 10A to 10E are cross-sectional views illustrating an example of a procedure of a method of forming a contact of a semiconductor memory device according to a comparative example;

FIGS. 11A and 11B are views illustrating an example of a configuration of a semiconductor memory device according to a modification of the first embodiment;

FIGS. 12A and 12B are cross-sectional views illustrating an example of a configuration of a semiconductor memory device according to a second embodiment; and

FIG. 13 is a cross-sectional view along the X direction illustrating a schematic configuration of a semiconductor memory device according to another embodiment.

### DETAILED DESCRIPTION

A semiconductor memory device according to an embodiment includes: a stacked body in which a plurality of first conductive layers and a plurality of first insulating layers are alternately stacked one by one and includes a stepped portion in which, the plurality of first conductive layers being processed in a stepped manner; a first pillar disposed in the stepped portion, the first pillar extending in a stacking direction of the stacked body; and a second pillar extending in the stacking direction within the stacked body at a position apart from the stepped portion in a first direction intersecting the stacking direction, the second pillar forming a memory cell at each intersection with at least a part of the plurality of first conductive layers. The first pillar has a semiconductor layer or a second conductive layer extending in the stacking direction and serving as a core material of the first pillar, and a second insulating layer covering a side wall of the semiconductor layer or the second conductive layer and serving as a liner layer of the first pillar.

The present invention will be described below in detail with reference to the drawings. The present invention is not limited by the following embodiments. The components in the following embodiments include those that one skilled in the art can readily assume or are substantially identical.

### First Embodiment

The first embodiment will be described below in detail with reference to the drawings.

(Configuration Example of Semiconductor Memory Device)

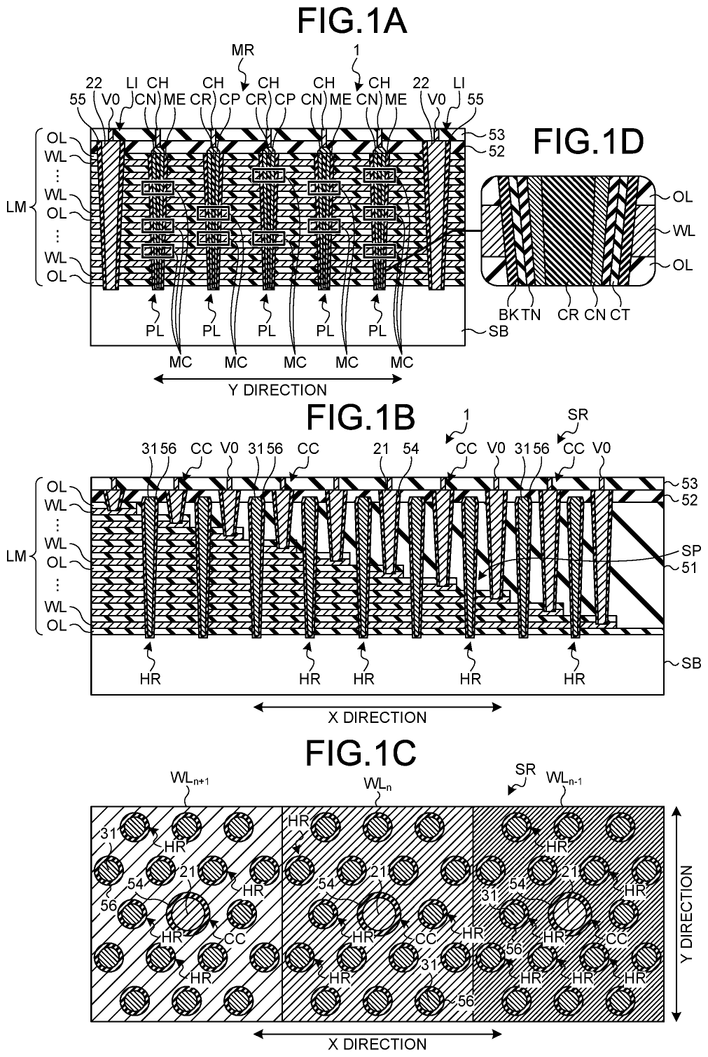

FIGS. 1A to 1D are views illustrating an example of a configuration of a semiconductor memory device 1 according to the first embodiment.

FIG. 1A is a cross-sectional view along the Y direction of the semiconductor memory device 1, and FIG. 1B is a cross-sectional view along the X direction of the semiconductor memory device 1. However, in FIGS. 1A and 1B, for example, some of the upper layer wiring and the like are omitted.

FIG. 1C is a plan view of the semiconductor memory device 1. However, in FIG. 1C, for example, insulating layers 51 to 53 on a word line WL is omitted. FIG. 1D is a partially enlarged cross-sectional view of a pillar PL.

In the present description, both the X direction and the Y direction are directions along the direction of the plane of the word line WL to be described below, and the X direction and the Y direction are orthogonal to each other. The electrical draw-out direction of the word line WL to be described below is sometimes referred to as a first direction, and the first direction is a direction along the X direction. The direction intersecting the first direction is sometimes referred to as a second direction, and the second direction is a direction along the Y direction. However, since the semiconductor memory device 1 may include manufacturing errors, the first direction and the second direction are not necessarily orthogonal to each other.

As illustrated in FIGS. 1A and 1B, the semiconductor memory device 1 includes a stacked body LM on a substrate SB. Insulating layers 52 and 53 are disposed on the stacked body LM in this order.

The substrate SB is, for example, a semiconductor substrate such as a silicon substrate. On the stacked body LM on the substrate SB, a plurality of word lines WL and a plurality of insulating layers OL are alternately stacked one by one.

The word lines WL as the plurality of first conductive layers are, for example, tungsten layers or molybdenum layers. The insulating layers OL as the plurality of first insulating layers are, for example, silicon oxide layers. The number of stacked layers of word lines WL and the number of stacked layers of insulating layers OL in the stacked body LM are arbitrary.

The stacked body LM may include one or more selection gate lines as the first conductive layer, further above the uppermost word line WL. The stacked body LM may include one or more selection gate lines as the first conductive layer, further below the lowermost word line WL. These selection gate lines are, for example, a tungsten layer or a molybdenum layer, similar to the word lines WL. These selection gate lines may be conductive polysilicon layers.

As illustrated in FIG. 1A, a plurality of plate-like contacts LI extending within the stacked body LM in the stacking direction of the stacked body LM and the direction along the X direction is disposed in the stacked body LM. More specifically, the plate-like contact LI penetrates the insulating layer 52 and the stacked body LM and reaches the substrate SB. The stacked body LM is divided by the plurality of plate-like contacts LI in the Y direction.

Each of the plurality of plate-like contacts LI includes an insulating layer 55, such as a silicon oxide layer, and a conductive layer 22, such as a tungsten layer or a conductive polysilicon layer. The insulating layer 55 covers the side wall of the plate-like contact LI facing in the Y direction. The conductive layer 22 is filled inside the insulating layer 55.

The bottom face of the conductive layer 22 is connected to the substrate SB such as a semiconductor substrate. The upper face of the conductive layer 22 is connected to a plug VO penetrating the insulating layer 53. The plug VO is connected to an upper layer wiring not illustrated in the figure. Such a configuration allows the plate-like contact LI to function as a source-line contact.

However, the stacked body LM may be divided in the Y direction by a plurality of plate-like portions formed of, for example, an insulating layer. In this case, the plate-like portion does not function as a source-line contact.

The stacked body LM is provided with a stepped region SR including a stepped portion SP and a memory region MR disposed apart from the stepped region SR in the X direction.

As illustrated in FIG. 1A, in the memory region MR, a plurality of pillars PL is disposed dispersedly between a plurality of plate-like contacts LI of the stacked body LM.

The pillar PL as a second pillar extends in the stacking direction within the stacked body LM. More specifically, the pillar PL has an upper end portion in the insulating layer 52, penetrates the stacked body LM, and reaches the substrate SB. The pillar PL has a cross-sectional shape in the direction along the XY plane, such as a circular shape, an elliptical shape, or an oblong shape (oval shape).

The pillar PL has a cap layer CP, a memory layer ME, a channel layer CN, and a core layer CR. The cap layer CP is disposed in the insulating layer 52 at the upper end portion of the pillar PL. The memory layer ME is disposed to cover the outer edge portion of the pillar PL. The channel layer CN is disposed inside the memory layer ME. The channel layer CN is also disposed at the lower end portion of the pillar PL. The core layer CR is filled inside the channel layer CN.

As illustrated in FIG. 1D, the memory layer ME has a multilayer structure in which a block insulating layer BK, a charge storage layer CT, and a tunnel insulating layer TN are stacked in this order from the outer peripheral side of the pillar PL.

The cap layer CP and the channel layer CN are, for example, semiconductor layers such as amorphous silicon layers or polysilicon layers. The block insulating layer BK, the tunnel insulating layer TN, and the core layer CR are, for example, a silicon oxide layer. The charge storage layer CT is, for example, a silicon nitride layer.

The cap layer CP is connected to a plug CH penetrating the insulating layers 53 and 52. The plug CH is connected to an upper layer wiring such as a bit line not illustrated in the figure. The upper end portion of the channel layer CN is connected to the cap layer CP. The lower end portion of the channel layer CN is connected to the substrate SB.

The configuration described above allows memory cells MC to be formed in portions of the side faces of the pillar PL facing the respective word lines WL. Thus, the semiconductor memory device 1 is configured as a three-dimensional nonvolatile memory in which memory cells are three-dimensionally disposed in the memory region MR, for example. Applying a predetermined voltage from the word line WL allows data to be written to and read from the memory cell MC.

When a selection gate line is disposed in an upper layer or a lower layer of the word line WL, a selection gate is formed on the side face of the pillar PL facing the selection gate line. Applying a predetermined voltage from the selection gate line allows the selection gate to be turned on or off, and the memory cell MC of the pillar PL to which the selection gate belongs to be set to a selected state or an unselected state.

As illustrated in FIG. 1B, a stepped region SR is disposed at an end portion of the stacked body LM in the X direction. The stepped region SR has a stepped portion SP where a plurality of word lines WL is processed in a stepped manner and terminated. The stepped portion SP is descended toward the outside of the stacked body LM.

The stepped portion SP is covered with the insulating layer 51. The insulating layer 51 has a height substantially equal to the upper face of the stacked body LM in, for example, the memory region MR, and extends to the outside of the stacked body LM. The insulating layers 52 and 53 on the upper face of the stacked body LM are also disposed on the insulating layer 51.

Each step of the stepped portion SP is formed of a pair of insulating layers OL and word lines WL in each layer. In other words, the word lines WL in each layer are drawn out to the respective steps of the stepped portion SP, and the insulating layers OL immediately above the word lines WL constitute the terrace face of the respective steps. In the present description, the direction in which the terrace face of each step of the stepped portion SP faces is defined as the upward direction.

A contact CC, which penetrates the insulating layers 52 and 51, and the insulating layer OL that constitutes the terrace face of each step, is connected to the word line WL that constitutes each step of the stepped portion SP. Each contact CC has a conductive layer 21 and an insulating layer 54.

The conductive layer 21 as the third conductive layer extends on the stepped portion SP in the stacking direction of the stacked body LM and serves as a core material of the contact CC. The conductive layer 21 is, for example, a tungsten layer or a copper layer. The insulating layer 54 as the third insulating layer covers the side wall of the conductive layer 21 and serves as a liner layer of the contact CC. The insulating layer 54 is, for example, a silicon oxide layer.

The lower end portion of the conductive layer 21 included in each contact CC is connected to the corresponding word line WL. The upper end portion of the conductive layer 21 is connected to the plug VO penetrating the insulating layer 53. The plug VO is connected to the upper layer wiring not illustrated in the figure.

The upper layer wiring is connected to a peripheral circuit, which is not illustrated in the figure, disposed around the stacked body LM. The peripheral circuit includes a plurality of transistors disposed on the substrate SB, for example, and contributes to the operation of the memory cell MC.

The above configuration allows a predetermined voltage to be applied to the memory cell MC from the peripheral circuit via the contact CC and the word line WL to operate the memory cell MC as a storage element.

A plurality of columnar portions HR is disposed dispersedly in the stepped region SR including the stepped portion SP.

The columnar portion HR as the first pillar extends in the stacking direction of the stacked body LM through the stepped portion SP. More specifically, the columnar portion HR has an upper end portion in the insulating layer 52 above the stepped portion SP, penetrates the insulating layer 51, and the stacked body LM of the stepped portion SP, and reaches the substrate SB. The columnar portion HR has a cross-sectional shape in the direction along the XY plane, such as a circular shape, an elliptical shape, or an oblong shape. The columnar portion HR has a semiconductor layer 31 and an insulating layer 56.

The semiconductor layer 31 extends in the stacking direction through the stepped portion SP and serves as a core material of the columnar portion HR. The semiconductor layer 31 is, for example, an amorphous silicon layer or a polysilicon layer. For example, the semiconductor layer 31 may be a layer in which amorphous silicon and polysilicon are mixed.

The insulating layer 56 as the second insulating layer covers the side wall and the bottom face of the semiconductor layer 31 and serves as a liner layer of the columnar portion HR. The insulating layer 56 is, for example, a silicon oxide layer.

The columnar portion HR having the above-described configuration does not contribute to the function of the semiconductor memory device 1. As will be described below, the columnar portion HR has a role of supporting these configurations when forming the stacked body LM from a stacked body in which the sacrificial layer and the insulating layer are stacked.

FIG. 1C illustrates three steps in the stepped portion SP. In these three steps, the (n−1)th word line WLₙ₋₁, the nth word line WLₙ, and the (n+1)th word line WLₙ₋₁ are drawn out from the lowermost word line WL.

Each of the contacts CC is disposed on the word lines WLₙ₋₁ to the WLₙ₊₁ and connected to the word lines WLₙ₋₁ to WLₙ₊₁. In the word lines WLₙ₋₁ to WLₙ₊₁, the plurality of columnar portions HR is disposed in, for example, a staggered manner when viewed from the stacking direction of the stacked body LM while avoiding interference with the contacts CC.

The area of the cross section of the columnar portion HR along the XY plane is smaller than, for example, the area of the cross section of the contact CC along the XY plane. Although not illustrated in the figure, the area of the cross section of the columnar portion HR along the XY plane is larger than, for example, the area of the cross section of the pillar PL along the XY plane.

In the memory region MR, the pillars PL are disposed in, for example, a staggered manner when viewed from the stacking direction of the stacked body LM. In such a case, the pitch between the plurality of pillars PL can be made smaller than, for example, the pitch between the plurality of columnar portions HR. Such a disposition of the plurality of pillars PL allows the disposition density of the pillars PL per unit area of the word lines WL in the stacked body LM to be increased, and the storage capacity of the semiconductor memory device 1 to be increased.

On the other hand, since the columnar portion HR is used exclusively for supporting the stacked body LM, the manufacturing load can be reduced by not using a precise configuration having a small cross-sectional area and a narrow pitch such as the pillar PL, for example.

(Method of Manufacturing Semiconductor Memory Device)

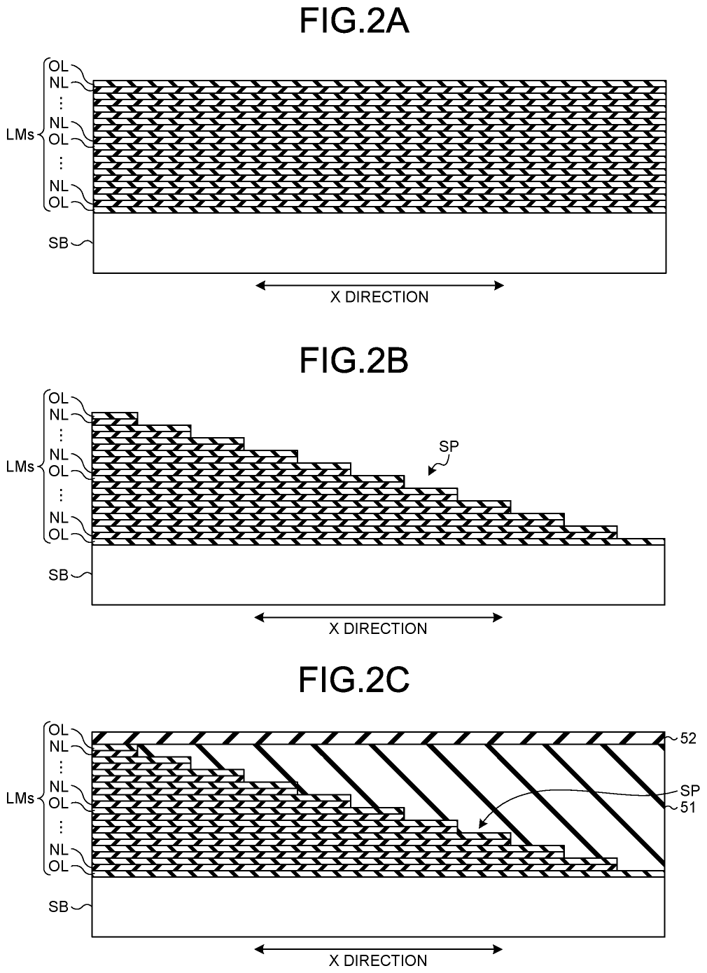

A method of manufacturing the semiconductor memory device 1 according to the first embodiment will then be described with reference to FIGS. 2A to 8C. FIGS. 2A to 8C are cross-sectional views illustrating an example of the procedure of the method of manufacturing the semiconductor memory device 1 according to the first embodiment.

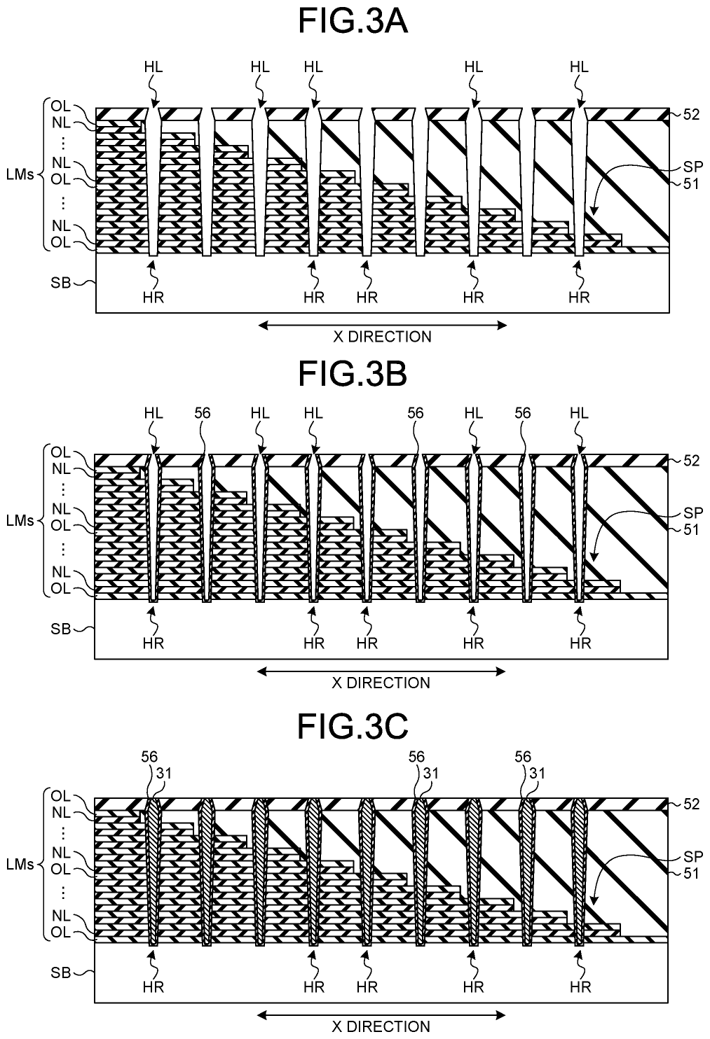

FIGS. 2A to 3C illustrate how the stepped portion SP is formed. FIGS. 2A to 3C illustrate a cross section along the X direction of a region that later serves as the stepped region SR, which correspond to FIG. 1B described above.

As illustrated in FIG. 2A, the stacked body LMs in which the plurality of insulating layers NL and the plurality of insulating layers OL are alternately stacked one by one is formed on the substrate SB such as a semiconductor substrate. The insulating layer NL is, for example, a silicon nitride layer, and functions as a sacrificial layer which is later replaced by a conductive material and becomes a word line WL.

As illustrated in FIG. 2B, at the end portion of the stacked body LMs in the X direction, the insulating layer NL and the insulating layer OL are processed in a stepped manner to form a stepped portion SP. The stepped portion SP is formed by repeating slimming of the mask pattern and etching of the insulating layer NL and the insulating layer OL of the stacked body LMs multiple times.

In other words, a mask pattern covering a part of the upper face of the stacked body LMs is formed by a resist layer or the like, and for example, the insulating layer NL and the insulating layer OL are etched away one by one. The area of the mask pattern is reduced by retreating the end portion of the mask pattern by treatment with oxygen plasma and the like, and the insulating layer NL and the insulating layer OL are etched away one by one.

The repetition of such treatment multiple times allows the insulating layer NL and the insulating layer OL at the end portion of the mask pattern to be processed in a stepped manner and terminated.

As illustrated in FIG. 2C, the insulating layer 51, such as a silicon oxide layer, is formed which covers the stepped portion SP and reaches the height of the upper face of the stacked body LMs. The insulating layer 51 is also formed in the peripheral region of the stacked body LMs. The insulating layer 52 covering the upper face of the stacked body LMs and the upper face of the insulating layer 51 is further formed.

As illustrated in FIG. 3A, a plurality of holes HL is formed in the stepped portion SP to penetrate the insulating layers 52 and 51, and the stacked body LMs of the stepped portion SP and reach the substrate SB. The plurality of holes HL is formed by plasma etching such as RIE (Reactive Ion Etching).

As illustrated in FIG. 3B, an insulating layer 56 is formed which covers the side face and the bottom face of the hole HL.

As illustrated in FIG. 3C, an amorphous silicon layer, a polysilicon layer, or the like is filled inside the insulating layer 56 to form the semiconductor layer 31. Thus, a plurality of columnar portions HR is formed in the stepped portion SP. At this point, however, the upper end portion of the columnar portion HR is exposed to the upper face of the insulating layer 52.

The semiconductor layer 31 may be, at the beginning of formation, an amorphous silicon layer or a layer in which amorphous silicon and polysilicon are mixed.

In this case, the entire semiconductor layer 31 may be changed into a polysilicon layer by the progress of crystallization at the timing of various heat treatments in the subsequent manufacturing process of the semiconductor memory device 1. Alternatively, in the semiconductor memory device 1 of the finished product, the semiconductor layer 31 may be left as an amorphous silicon layer or a mixed layer of amorphous silicon and polysilicon.

The semiconductor layer 31 may consistently maintain the state of the polysilicon layer from the initial formation to the semiconductor memory device 1 of the finished product.

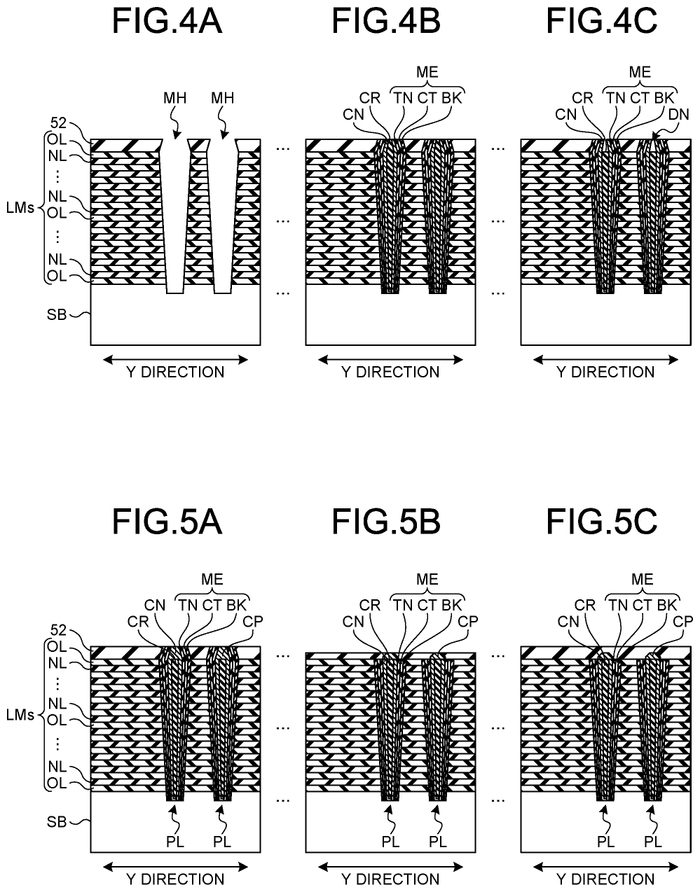

FIGS. 4A to 5C now illustrate how the pillars PL are formed.

FIGS. 4A to 5C illustrate cross sections along the Y direction of regions that later become memory regions MR. However, as described above, the pillar PL is circular, elliptical, oblong, or the like, and therefore has the same cross-sectional shape regardless of the direction of the cross section.

As illustrated in FIG. 4A, also in the region where the memory region MR is to be formed, the stacked body LMs is formed on the substrate SB by the various processes described above, and the insulating layer 52 is formed on the stacked body LMs. In this state, a plurality of memory holes MH is formed which penetrates the insulating layer 52 and the stacked body LMs and reaches the substrate SB.

As illustrated in FIG. 4B, the memory layer ME in which the block insulating layer BK, the charge storage layer CT, and the tunnel insulating layer TN are stacked is formed in the memory hole MH in order from the outer peripheral side of the memory hole MH. As described above, the block insulating layer BK and the tunnel insulating layer TN are, for example, a silicon oxide layer, and the charge storage layer CT is, for example, a silicon nitride layer.

The memory layer ME is also formed on the bottom face of the memory hole MH and then removed.

A channel layer CN such as an amorphous silicon layer or a polysilicon layer is formed inside the tunnel insulating layer TN. The channel layer CN is also formed on the bottom face of the memory hole MH. A core layer CR such as a silicon oxide layer is filled further inside the channel layer CN.

As illustrated in FIG. 4C, the core layer CR exposed on the upper face of the insulating layer 52 is etched away to a predetermined depth to form a recess DN.

As illustrated in FIG. 5A, the interior of the recess DN is filled with an amorphous silicon layer, a polysilicon layer, or the like to form a cap layer CP. Thus, a plurality of pillars PL is formed.

As illustrated in FIG. 5B, the insulating layer 52 is etched back together with the top face of the cap layer CP. Thus, the thickness of the cap layer CP is reduced.

As illustrated in FIG. 5C, the insulating layer 52 thinned by the etching back is additionally stacked. Thus, the upper face of the cap layer CP is covered with the insulating layer 52.

The processes for forming the stepped portions SP in FIGS. 2B and 2C, the processes for forming the columnar portions HR in FIGS. 3A to 3C, and the processes for forming the pillars PL in FIGS. 4A to 5C can be interchanged in the order of the processes.

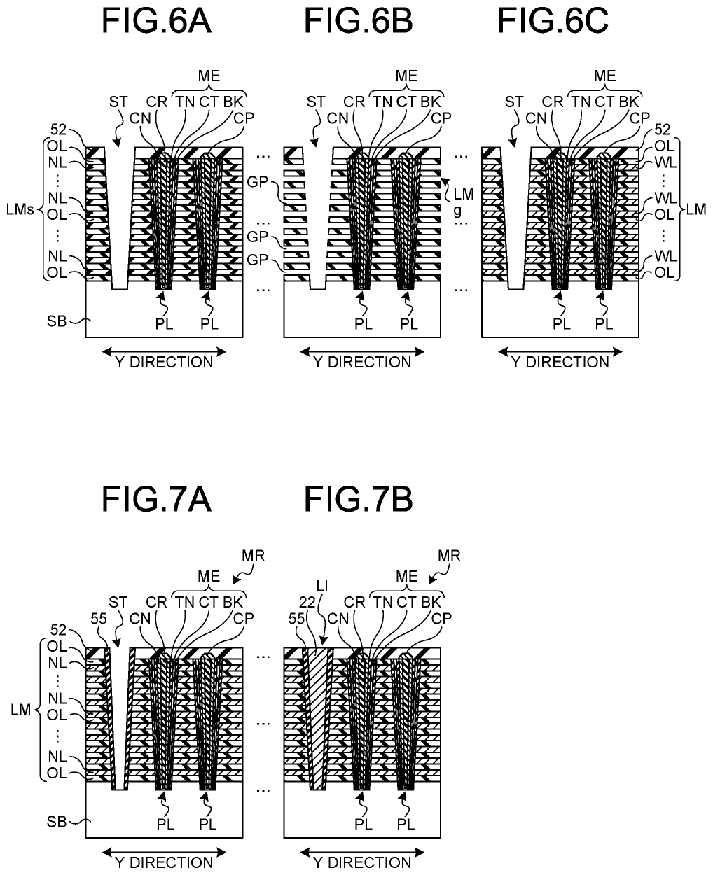

FIGS. 6A to 6C now illustrate how the stacked body LM is formed from the stacked body LMs. FIGS. 6A to 6C illustrate cross sections along the Y direction of regions that later become memory regions MR, as in FIGS. 4A to 5C.

As illustrated in FIG. 6A, a slit ST is formed which penetrates the insulating layer 52 and the stacked body LMs and reaches the substrate SB. A plurality of slits ST is formed apart from each other in the Y direction, and extends in the direction along the X direction through the stacked body LMs from the memory region MR to the stepped region SR.

As illustrated in FIG. 6B, the insulating layer NL of the stacked body LMs is removed by flowing a removing liquid of the insulating layer NL such as hot phosphoric acid into the stacked body LMs from the slit ST. Thus, the insulating layers NL between the insulating layers OL are removed to form a stacked body LMg having a plurality of gap layers GP.

The stacked body LMg including the plurality of gap layers GP has a fragile structure. In the memory region MR, the plurality of pillars PL supports such a fragile stacked body LMg. In the stepped region SR, the plurality of columnar portions HR supports the stacked body LMg. Such a supporting structure such as the pillar PL and the columnar portion HR suppress the remaining insulating layer OL from being bent and the stacked body LMg from being distorted or collapsed.

As illustrated in FIG. 6C, a raw material gas of an electric conductor such as tungsten or molybdenum is injected from the slit ST into the stacked body LMg, and the gap layer GP of the stacked body LMg is filled to form a plurality of word lines WL. Thus, a stacked body LM is formed in which a plurality of word lines WL and a plurality of insulating layers OL are alternately stacked one by one.

The process of removing the insulating layer NL and forming the word lines WL illustrated above in FIGS. 6A to 6C may be referred to as a replacement process.

FIGS. 7A and 7B now illustrate how the plate-like contact LI is formed from the slit ST. FIGS. 7A and 7B illustrate cross sections of the memory region MR along the Y direction, as in, for example, FIGS. 6A to 6C.

As illustrated in FIG. 7A, the insulating layer 55 is formed on a side wall facing the Y direction of the slit ST.

As illustrated in FIG. 7B, the conductive layer 22 is filled inside the insulating layer 55, thereby forming the plate-like contact LI.

However, in spite of the examples illustrated in FIGS. 7A and 7B, an insulating layer such as a silicon oxide layer may be filled in the slit ST to form a plate-like portion which does not function as a source-line contact.

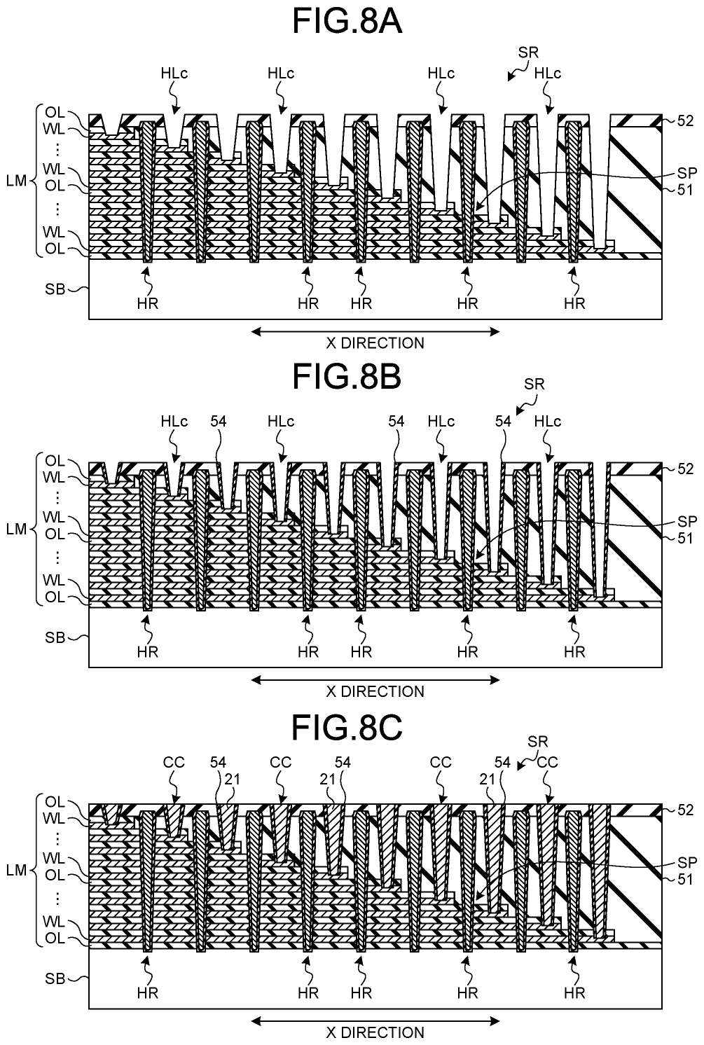

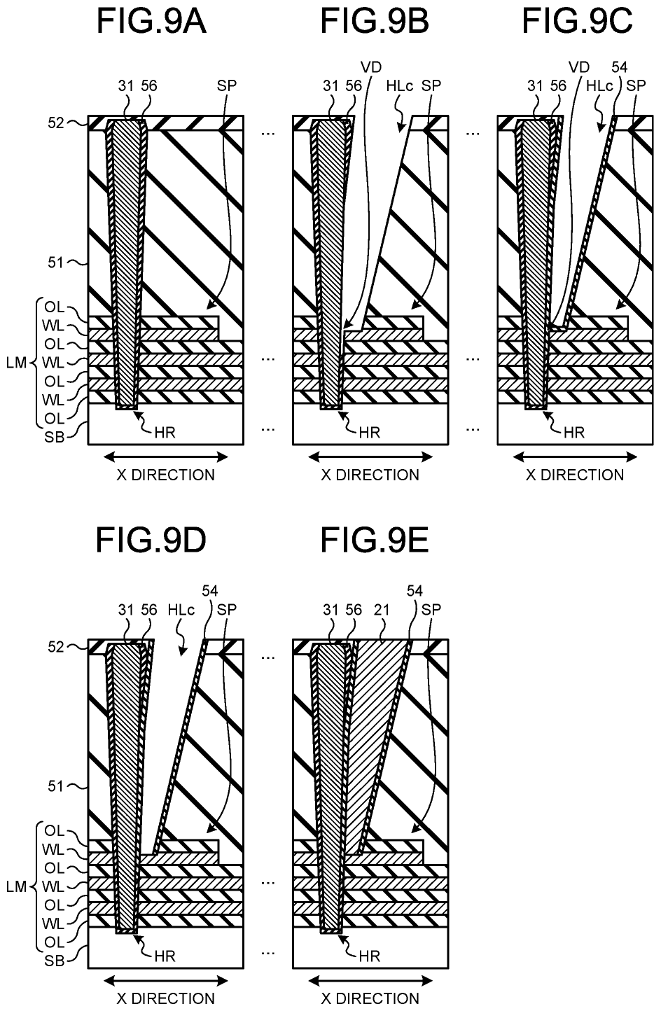

FIGS. 8A to 9E now illustrate how the contact CC is formed in the stepped portion SP.

FIGS. 8A to 8C illustrate cross sections along the X direction of the stepped region SR, as in FIGS. 2A to 3C and correspond to FIG. 1B described above.

As illustrated in FIG. 8A, also in the stepped region SR, after the process illustrated in FIG. 3C described above, the upper end portion of the columnar portion HR is etched back by the process illustrated in FIGS. 4A to 5C, the insulating layer 52 is additionally stacked, and the upper face of the columnar portion HR is covered with the insulating layer 52.

By the replacement process illustrated in FIGS. 6A to 6C, the insulating layer NL is replaced with the word line WL even in the stepped region SR to constitute a part of the stacked body LM.

In this state, a plurality of contact holes HLc is formed which penetrates the insulating layers 52 and 51 and further penetrates the insulating layer OL constituting the terrace portion of each step of the stepped portion SP to reach the word lines WL of each step. The plurality of contact holes HLc is formed collectively by plasma etching such as RIE.

More specifically, a plurality of contact holes HLc having different reaching depths can be formed collectively by stopping etching the lower end portions of the respective contact holes HLc by, for example, word lines WL of respective steps serving as reaching targets.

As illustrated in FIG. 8B, an insulating layer 54 such as a silicon oxide layer serving as a liner layer of the contact CC is formed on each side wall of the plurality of contact holes HLc.

As illustrated in FIG. 8C, a tungsten layer, a copper layer, or the like is filled inside the insulating layer 54 to form a conductive layer 21 serving as a core material of the contact CC. Thus, a plurality of contacts CC is formed which is each connected to the plurality of word lines WL.

In the manufacturing process of the semiconductor memory device 1 described above, at least either of the columnar portion HR and the contact CC may be formed to be inclined.

The factor of the inclination of the columnar portion HR includes that for example, the hole HL is formed to be inclined in the process in FIG. 3A described above. The reason why the hole HL is processed by being inclined is that ions generated in the plasma may be incident obliquely to the substrate SB in, for example, plasma etching. During the replacement process in FIGS. 6A to 6C described above, the stacked body LMg having a plurality of gap layers GP may be distorted, and the columnar portions HR that have already been formed may be inclined accordingly.

The factor of the inclination of the contact CC includes that for example, in the process in FIG. 8A described above, ions generated in the plasma are incident obliquely to the substrate SB, and the contact hole HLc is formed to be inclined.

The case where at least either of the columnar portion HR and the contact CC is formed to be inclined includes that at least either of the columnar portion HR and the contact CC is formed to have a bent shape or is formed to be bent from the middle. Thus, the angle of inclination in the extending direction of the columnar portion HR and the contact CC may not be constant.

A part or the whole of at least one of the columnar portion HR and the contact CC is intersected obliquely to the other, whereby, for example, the lower end portion of the contact CC may come into contact with the side face of the columnar portion HR adjacent to the contact CC.

FIGS. 9A to 9E are examples of how the lower end portion of the contact CC is formed in contact with the side face of the columnar portion HR. FIGS. 9A to 9E are partially enlarged cross-sectional views along the X direction of the stepped portion SP, and illustrate steps including the third word line WL from the lowest layer.

The example in FIGS. 9A to 9E illustrates a case where the columnar portion HR is formed substantially perpendicular to the substrate SB and the contact hole HLc is formed so as to be inclined with respect to the columnar portion HR, whereby the lower end portion of the contact CC comes into contact with the columnar portion HR.

However, the contact CC is also formed as in the example of FIGS. 9A to 9E, in the case where the contact CC substantially perpendicular to the substrate SB comes into contact with the columnar portion HR formed to be inclined with respect to the substrate SB, or in the case where the contact CC inclined with respect to the substrate SB comes into contact with the columnar portion HR.

As illustrated in FIG. 9A, a columnar portion HR has been formed in the stepped portion SP, and the insulating layer NL of the stepped portion SP has been replaced with the word line WL by replacement process.

As illustrated in FIG. 9B, the contact hole HLc is formed at a position in close proximity to the columnar portion HR by being inclined toward the columnar portion HR side, for example. In such a case, for example, the lower end portion of the contact hole HLc comes into contact with the side face of the columnar portion HR.

The etching condition for processing the contact hole HLc is adjusted so as to obtain a high etching rate for the insulating layers 52 and 51. Therefore, the insulating layer 56 is partially removed on the side face of the columnar portion HR contacted with the contact hole HLc, and the semiconductor layer 31 as the core material of the columnar portion HR is exposed in the contact hole HLc.

However, the above-described etching condition is adjusted so as to obtain high selectivity with respect to the semiconductor layer 31, and the lower end portion of the contact hole HLc is etch-stopped at the semiconductor layer 31 of the columnar portion HR. Thus, the inside of the columnar portion HR is suppressed from being etched away in a wide range.

However, even in this case, plasma etching proceeds while removing the insulating layer 56 on the side face of the columnar portion HR, and the lowermost end of the contact hole HLc may reach, for example, a position below the word line WL as the reaching target. Thus, a void VD extending from the lower end portion of the contact hole HLc on the word line WL along the side face of the semiconductor layer 31 may be formed at a position below the word line WL as the reaching target. The void VD is a space which is about the thickness of the insulating layer 56 formed by removing the insulating layer 56 of the columnar portion HR.

As illustrated in FIG. 9C, the insulating layer 54 is formed which covers the side wall and the bottom face of the contact hole HLc. In such a case, the semiconductor layer 31 of the columnar portion HR exposed in the contact hole HLc is also covered with the insulating layer 54. In such a case, for example, the insulating layer 54 is formed so as to have a layer thickness larger than or equal to that of the insulating layer 56 of the columnar portion HR. Thus, the void VD at the lower end portion of the contact hole HLc is almost completely filled with the insulating layer 54.

As illustrated in FIG. 9D, the insulating layer 54 on the bottom face of the contact hole HLc is removed by plasma etching such as RIE. Thus, the upper face of the word line WL to be connected is exposed in the contact hole HLc.

In such a case, the use of an etching condition having high anisotropy allows the insulating layer 54 covering the side wall of the contact hole HLc and the side wall of the semiconductor layer 31 of the columnar portion HR to be left without being removed. Since the void VD at the lower end portion of the contact hole HLc has an extremely high aspect ratio, the progress of plasma etching into the void VD is suppressed. Therefore, the insulating layer 54 filled with the void VD is not removed and remains.

As illustrated in FIG. 9E, the conductive layer 21 is filled inside the insulating layer 54. Thus, the contact CC is formed in which the lower end portion of the conductive layer 21 is connected to the word line WL. However, since the insulating layer 54 is filled in the void DV, the conductive layer 21 does not reach below the word line WL to be connected, and for example, contact with the word line WL below the word line WL to be connected is suppressed.

The semiconductor layer 31 of the columnar portion HR exposed in the contact hole HLc is covered with the insulating layer 54. Therefore, the contact between the semiconductor layer 31 and the conductive layer 21 of the contact CC is suppressed, and the influence on the electrical characteristics of the contact CC, for example, is suppressed.

As described above, the contact CC connected to the word line WL to be connected is formed even when the contact CC comes into contact with the columnar portion HR.

In this case, between the semiconductor layer 31 of the columnar portion HR and the conductive layer 21 of the contact CC, there may be a portion in which the insulating layer 56 is not interposed in at least a portion in the stacking direction of the stacked body LM.

However, even in this case, at least the insulating layer 54 is interposed between the semiconductor layer 31 of the columnar portion HR and the conductive layer 21 of the contact CC. In other words, in this case, the semiconductor layer 31 of the columnar portion HR is in contact with the insulating layer 54 of the contact CC in a part of the stacking direction of the stacked body LM. Thus, the semiconductor layer 31 of the columnar portion HR and the conductive layer 21 of the contact CC are insulated by at least the insulating layer 54.

The contact area of the lower end portion of the contact CC with the upper face of the word line WL becomes narrower than usual by the contact with the columnar portion HR. However, if the contact area of half or more of the contact area of the lower end portion of the normal contact CC with the upper face of the word line WL is obtained, sufficient electrical conduction between the conductive layer 21 and the word line WL is ensured.

The insulating layer 53 is then formed on the insulating layer 52, and the plug VO is formed which is connected to each of the plate-like contact LI and the contact CC through the insulating layer 53. The plug CH is formed which is connected to the pillar PL through the insulating layers 53 and 52. Further, upper layer wiring and the like are formed which are connected to each of the plugs VO and CH.

As described above, the semiconductor memory device 1 of the first embodiment is manufactured.

### Comparative Example

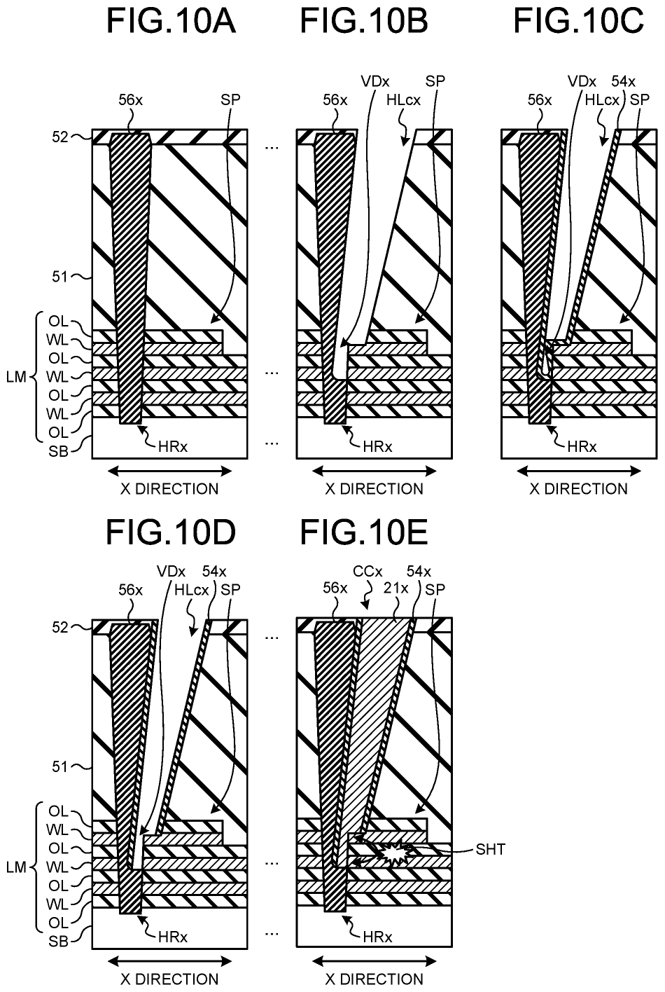

A semiconductor memory device of a comparative example will then be described with reference to FIGS. 10A to 10E. FIGS. 10A to 10E are cross-sectional views illustrating an example of the procedure of the method of forming a contact CCx of the semiconductor memory device according to the comparative example. More specifically, FIGS. 10A to 10E are partially enlarged cross-sectional views along the X direction of the stepped portion SP provided in the semiconductor memory device of the comparative example, and illustrate a step including the third word line WL from the lowest layer.

As described above, the columnar portion used exclusively for supporting the stacked body may more conveniently be constituted of, for example, only a single insulating layer. As illustrated in FIG. 10A, the columnar portion HRx of the semiconductor memory device of the comparative example is constituted of an insulating layer 56x such as a silicon oxide layer extending in the stacking direction of the stacked body LM.

In the stepped portion SP in which such a columnar portion HRx is formed, as will be described below, a short circuit may occur between the plurality of word lines WL by the contact CCx for drawing out the word lines WL to the upper layer wiring.

As illustrated in FIG. 10B, it is assumed that the contact hole HLcx is formed to be intersected obliquely in close proximity to the columnar portion HRx and is in contact with the columnar portion HRx at the lower end portion thereof.

In the etching condition of the contact hole HLcx, for example, the insulating layer 56x of the columnar portion HRx is etched at a high etching rate. Therefore, depending on the degree of oblique angle of the contact hole HLcx, the portion from the side wall side of the columnar portion HRx to the vicinity of the center portion is eroded by the contact hole HLcx.

As in the example of FIG. 10B, the plasma etching proceeds downward in the columnar portion HRcx to form a space VDx which extends from the lower end portion of the contact hole HLcx on the word line WL as the reaching target to the depth position of the word line WL in the lower layer, and the side end portion of the word line WL in the lower layer may be exposed within the columnar portion HRx.

As illustrated in FIG. 10C, an insulating layer 54x is formed which covers the side wall and the bottom face of the contact hole HLcx. The insulating layer 54x covers the upper face of the word line WL as the reaching target and also covers the etching end face of the side face of the columnar portion HRx eroded by the contact hole HLcx.

However, at the lower end portion of the contact hole HLcx, the space VDx is formed which extends to a word line WL below the word line WL as the reaching target within the columnar portion HRx. Since the space VDx has a relatively large volume, for example, as in the example of FIG. 10C, the insulating layer 54x may be filled in the space VDx with voids. Alternatively, the upper portion of the space VDx may not be completely closed, and the insulating layer 54x may be formed with an opening in the contact hole HLcx.

As illustrated in FIG. 10D, the insulating layer 54x on the bottom face of the contact hole HLcx is removed. The insulating layer 54x here is incompletely filled with voids contained in the space VDx, or is formed with an opening above the space VDx. Therefore, a part or the whole of the insulating layer 54x is removed from the space VDx.

Since the space VDx has a relatively large volume and a relatively low aspect ratio, plasma etching easily proceeds even in the space VDx. Thus, the removal of the insulating layer 54x from the space VDx can be further progressed.

In the space VDx from which a part or the whole of the insulating layer 54x has been removed, for example, a side end portion of a word line WL below the word line WL to be reached by the contact hole HLcx is exposed.

As illustrated in FIG. 10E, a conductive layer 21x is filled inside the insulating layer 54x. Thus, the contact CCx is formed.

In such a case, the conductive layer 21x is connected to the word line WL to be connected exposed at the lower end portion of the contact hole HLcx, is also filled in the space VDx from which the insulating layer 54x has been removed, and is also connected, for example, to a side end portion of a word line WL below the word line WL to be connected.

Thus, a short circuit failure SHT occurs between the word line WL to be connected by the contact CCx and a word line WL below the word line WL.

According to the semiconductor memory device 1 of the first embodiment, the columnar portion HR has a semiconductor layer 31 that extends in the stacking direction of the stacked body LM and serves as a core material of the columnar portion HR, and an insulating layer 56 that covers the side wall of the semiconductor layer 31 and serves as a liner layer of the columnar portion HR.

Thus, even when the contact CC and the columnar portion HR come into contact with each other, the short circuit failure in the contact CC can be suppressed. Since contact between the contact CC and the columnar portion HR is permitted to a certain degree, for example, the distance between the contact CC and the columnar portion HR can be reduced, and the columnar portion HR can be disposed in the stepped portion SP at a higher density to suppress, for example, collapse of the stacked body LMg.

According to the semiconductor memory device 1 of the first embodiment, the layer thickness of the insulating layer 54 of the contact CC in the direction along each layer of the stacked body LM is larger than or equal to the layer thickness of the insulating layer 56 of the columnar portion HR in the direction along each layer of the stacked body LM.

Thus, even when the void VD is formed which extends from the lowermost end of the contact hole HLc to the word line WL in the lower layer, the void VD can be filled with the insulating layer 54. Therefore, contact between the word line WL in the lower layer and the conductive layer 21 of the contact CC can be suppressed.

According to the semiconductor memory device 1 of the first embodiment, even when the lower end portion of the contact CC is in contact with the side face of the columnar portion HR, at least the insulating layer 54 of the contact CC is interposed between the semiconductor layer 31 serving as the core material of the columnar portion HR and the conductive layer 21 of the contact CC.

Thus, the contact between the semiconductor layer 31 and the conductive layer 21 is suppressed, and the influence on the electrical characteristics of the contact CC, for example, can be suppressed.

According to the method of manufacturing the semiconductor memory device 1 of the first embodiment, when the lower end portion of the contact hole HLc comes into contact with the side face of the columnar body HR, the lower end portion of the contact hole HLc is etch-stopped at least by the semiconductor layer 31 of the columnar portion HR.

Thus, the columnar portion HR is suppressed from being largely eroded by the contact hole HLc. Even when the void VD described above is formed at the lower end portion of the contact hole HLc, the void VD can be kept small. Therefore, the void VD is easily filled by the insulating layer 54. When the insulating layer 54 on the bottom face of the contact hole HLc is removed, the insulating layer 54 in the void VD can be suppressed from being removed.

(Modification)

In the first embodiment described above, it has been assumed that the columnar portion HR is disposed in the stepped region SR. However, a columnar portion for supporting the stacked body may also be disposed in the memory region. In the memory region, for example, the above-described short-circuit failure between word lines does not occur. Therefore, a columnar portion can also be disposed in the memory region, which does not have a core material but is constituted of only an insulating layer or the like.

However, when the columnar portion HR described above is disposed in the stepped region, the columnar portion HR is preferably disposed in the memory region as well. The reason for such a disposition is because it is not required to form separate the columnar portions HR for the stepped region and the memory region, which can reduce the manufacturing load on the semiconductor memory device and thus reduce the manufacturing cost.

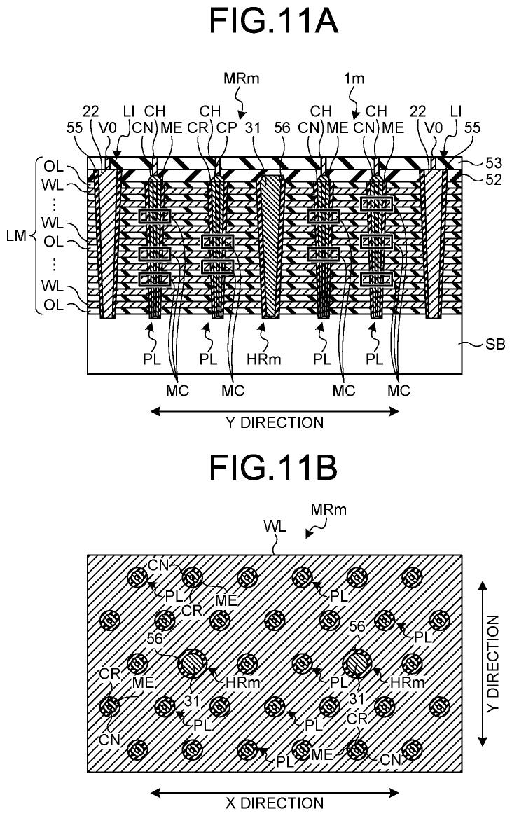

FIGS. 11A and 11B illustrate a semiconductor memory device 1m of a modification of the first embodiment having the above configuration.

FIGS. 11A and 11B are views illustrating an example of the configuration of the semiconductor memory device 1m according to the modification of the first embodiment.

FIG. 11A is a cross-sectional view along the X direction, which includes a memory region MRm of the semiconductor memory device 1m. However, in FIG. 11A, some of the upper layer wiring and the like are omitted. FIG. 11B is a cross-sectional view along the XY plane of the memory region MRm of the semiconductor memory device 1m. The cross-sectional view of FIG. 11B illustrates a cross section of a word line WL in an arbitrary layer.

In FIGS. 11A and 11B, the same components as those of the semiconductor memory device 1 of the first embodiment described above are denoted by the same reference numerals, and the description thereof is omitted.

As illustrated in FIG. 11A, in the memory region MRm of the semiconductor memory device 1m, a columnar portion HRm is disposed which has the same configuration as the columnar portion HR of the first embodiment described above.

In other words, the columnar portion HRm as the first pillar extends in the stacking direction within the stacked body LM in the memory region ME and reaches the substrate SB. The columnar portion HRm has a semiconductor layer 31 extending in the stacking direction of the stacked body LM and serving as a core material of the columnar portion HRm, and an insulating layer 56 covering a side wall of the semiconductor layer 31 and serving as a liner layer of the columnar portion HRm.

As illustrated in FIG. 11B, the plurality of pillars PL is disposed in a staggered manner, for example, when viewed from, the stacking direction of the stacked body LM in the memory region MRm. The plurality of columnar portions HRm is disposed dispersedly between the pillars PL. In the memory region MRm, the disposition density of the columnar portions HRm is lower than, for example, that of the pillars PL. Thus, the storage capacity of the semiconductor memory device 1m can be increased. However, the ratio of the columnar portion HRm to the pillar PL is arbitrary.

The columnar portion HRm has a cross-sectional shape in the direction along the XY plane, such as a circular shape, an elliptical shape, or an oblong shape. The area of the cross section of the columnar portion HR along the XY plane is larger than, for example, the area of the cross section of the pillar PL along the XY plane.

Although not illustrated in the figure, also in the semiconductor memory device 1m, it is assumed that the plurality of columnar portions HR is disposed dispersedly in the stepped region.

The semiconductor memory device 1m of the modification has the same effect as the semiconductor memory device 1 of the first embodiment described above.

### Second Embodiment

A second embodiment will be described below in detail with reference to the drawings. The semiconductor memory device of the second embodiment is different from the first embodiment in that the semiconductor memory device according to the second embodiment is of a two-tier type in which the stacked bodies are stacked in two steps.

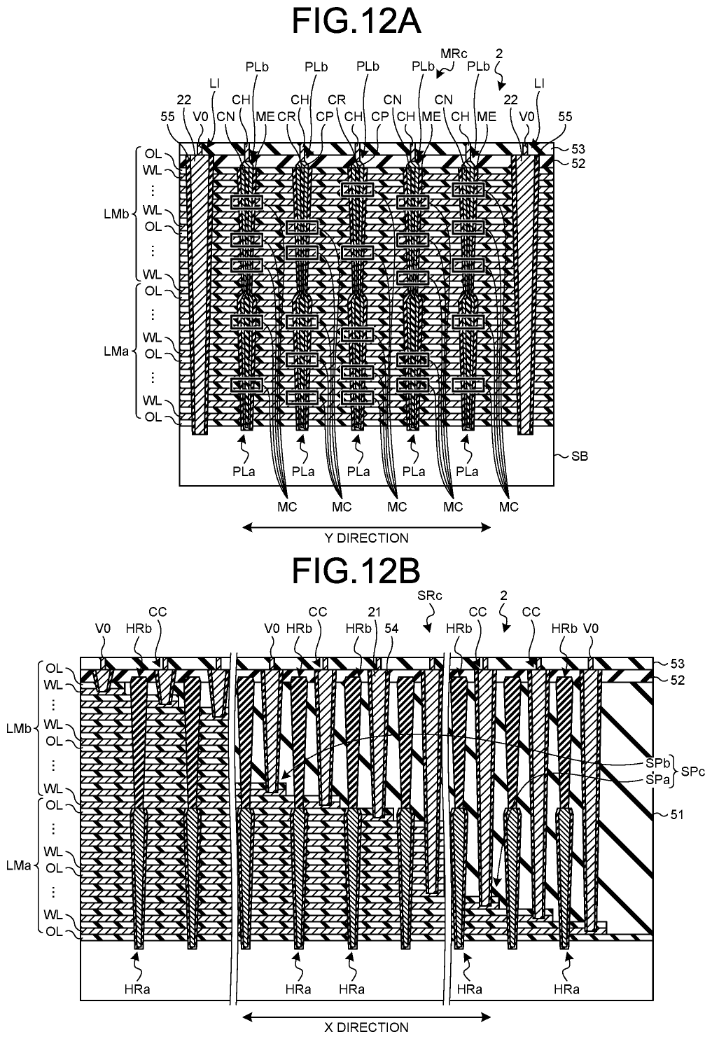

FIGS. 12A and 12B are cross-sectional views illustrating an example of the configuration of a semiconductor memory device 2 according to the second embodiment. FIG. 12A is a cross-sectional view along the Y direction, which includes the memory region MRc of the semiconductor memory device 2. FIG. 12B is a cross-sectional view along the X direction, which includes the stepped region SRc of the semiconductor memory device 2.

However, in FIGS. 12A and 12B, some of the upper layer wiring and the like are omitted. In FIG. 12B, some steps of the stepped portion SPc are omitted.

In FIGS. 12A and 12B, the same components as those of the semiconductor memory device 1 of the first embodiment described above are denoted by the same reference numerals, and the description thereof is omitted.

As illustrated in FIGS. 12A and 12B, the semiconductor memory device 2 includes a lower stacked body LMa and an upper stacked body LMb stacked in two steps.

The lower stacked body LMa has the same configuration as the stacked body LM of the first embodiment described above. In other words, the lower stacked body LMa has a configuration in which word lines WL as a plurality of first conductive layers and insulating layers OL as a plurality of first insulating layers are alternately stacked one by one on the substrate SB.

The lower stacked body LMa has pillars PLa as a plurality of second pillars which is disposed dispersedly in the memory region MRc, penetrates the lower stacked body LMa, and reach the substrate SB. The pillar PLa has the same configuration as the pillar PL of the first embodiment described above except that the pillar PLa does not include the cap layer CP.

The lower stacked body LMa has a lower stepped portion SPa disposed in the stepped region SRc at the end in the X direction. The lower stepped portion SPa has the same configuration as the stepped portion SP of the first embodiment described above. In other words, the lower stepped portion SPa has a configuration in which a plurality of word lines WL and a plurality of insulating layers OL are processed in a stepped manner and terminated, and the lower stepped portion SPa is descended toward the outside of the lower stacked body LMa.

The lower stacked body LMa has columnar portions HRa as a plurality of first pillars which is disposed dispersedly in the stepped region SRc. Each of the plurality of columnar portions HRa has the same configuration as that of the columnar portion HR of the first embodiment described above. In other words, the columnar portion HRa has a semiconductor layer 31 extending in the stacking direction of the lower stacked body LMa and serving as a core material of the columnar portion HRa and reaching the substrate SB, and an insulating layer 56 covering the side wall and bottom face of the semiconductor layer 31 and serving as a liner layer of the columnar portion HRa.

A part of the columnar portions HRa of the plurality of columnar portions HRa is disposed in the lower stepped portion SPa. The other part of the columnar portions HRa of the plurality of columnar portions HRa penetrates the lower stacked body LMa at a position overlapping an upper stepped portion SPb to be described below of the upper stacked body LMb in the stacking direction, that is, at a position below the upper stepped portion SPb.

The upper stacked body LMb is disposed on the lower stacked body LMa, and has a configuration in which word lines WL as a plurality of first conductive layers and insulating layers OL as a plurality of first insulating layers are alternately stacked one by one.

The upper stacked body LMb has pillars PLb as a plurality of fourth pillars which are disposed dispersedly in the memory region MRc, penetrate the upper stacked body LMb, and are each connected to the upper end portions of the plurality of pillars PLa. The pillar PLb has the same configuration as the pillar PL of the first embodiment described above.

In other words, the pillar PLb has a configuration that has a cap layer CP at the upper end portion, has a memory layer ME and a channel layer CN disposed in the pillar in this order from the outer peripheral side, and has a core layer CR filled inside the channel layer CN. The channel layer CN is also disposed on the bottom face of the pillar PLa and is connected to the channel layer CN of the corresponding pillar PLa. The memory layer ME of the pillar PLb is also connected to the memory layer ME of the pillar PLa at a position outside the channel layer CN.

As described above, the pillars provided in the semiconductor memory device 2 include a plurality of pillars PLa disposed in the lower stacked body LMa, and a plurality of pillars PLb disposed in the upper stacked body LMb, the lower end portions of which are each connected to the upper end portions of the plurality of pillars PLa.

The upper stacked body LMb has an upper stepped portion SPb disposed in the stepped region SRc at the end in the X direction. The upper stepped portion SPb has a configuration in which a plurality of word lines WL and a plurality of insulating layers OL are processed in a stepped manner and terminated.

The lowermost step of the upper stepped portion SPb is disposed above the uppermost step of the lower stepped portion Spa described above and closer to the memory region MRc than the uppermost step of the lower stepped portion SPa. In other words, the upper stepped portion SPb is continuously ascended from the uppermost step of the lower stepped portion SPa described above toward the memory region MR.

Thus, the stepped portion SPc is constituted which is continuously ascended from the lower stepped portion SPa to the upper stepped portion SPb in the direction approaching the memory region MR.

The upper stacked body LMb has columnar portions HRb serving as a plurality of third pillars disposed dispersedly in the stepped region SRc. Each of the plurality of columnar portions HRb is, for example, an insulator such as a silicon oxide layer, which extends in the stacking direction of the upper stacked body LMb and is connected to the upper end portions of the plurality of columnar portions HRa.

More specifically, a part of the columnar portions HRb of the plurality of columnar portions HRb is disposed at a position overlapping the lower stepped portion SPa in the stacking direction, that is, at an upper position of the lower stepped portion SPa. These columnar portions HRb penetrate the insulating layer 52 to extend within the insulating layer 51 in the stacking direction of the upper stacked body LMb. The lower end portion of each of the columnar portions HRb is connected to the upper end portion of each of the columnar portions HRa disposed on each step of the lower stepped portion SPa.

The other part of the columnar portions HRb of the plurality of columnar portions HRb is disposed on each step of the upper stepped portion SPb. These columnar portions HRb penetrate the insulating layers 52 and 51 and the respective layers of the upper stepped portion SPb, and are each connected to upper end portions of the plurality of columnar portions HRa disposed in the lower stacked body LMa at positions below the upper stepped portion SPb.

As described above, the columnar portion provided in the semiconductor memory device 2 includes a plurality of columnar portions HRa disposed in the lower stacked body LMa, and a plurality of columnar portions HRb disposed in the upper stacked body LMb, the lower end portions of which are each connected to the upper end portions of the plurality of columnar portions HRa.

On the other hand, the plate-like contact LI having the same configuration as that of the first embodiment described above penetrates the insulating layer 52, the upper stacked body LMb, and the lower stacked body LMa and reaches the substrate SB without being divided into the upper and lower structures.

The plurality of plate-like contacts LI extends in the direction along the X direction through the upper stacked body LMb and the lower stacked body LMa. Thus, both the upper stacked body LMb and the lower stacked body LMa are divided in the Y direction. However, the upper stacked body LMb and the lower stacked body LMa may be divided in the Y direction by a plate-like portion having no conductive layer 22.

A plurality of contacts CC is disposed on each step of the upper stepped portion SPb and on each step of the lower stepped portion SPa, and is connected to each of the word lines WL constituting these each step. Thus, the word line WL in each layer is drawn out to the upper layer wiring not illustrated in the figure, in the upper stepped portion SPb and the lower stepped portion SPa.

As in the case of the first embodiment described above, there is a possibility that these contacts CC also come into contact with the adjacent columnar portions HRa and HRb. In such a case, the contact CC extending to a deeper position in the stacking direction and connected to each word line WL of the lower stepped portion SPa has a high probability of contacting with the columnar portion HRa disposed in the lower stepped portion SPa.

Therefore, as described above, in the semiconductor memory device 2, the columnar portion HRa having the same configuration as that of the columnar portion HR of the first embodiment described above is disposed at the lower stepped portion SPa and at a position in the lower stacked body LMa overlapping the upper stepped portion SPb in the stacking direction.

On the other hand, as described above, in the upper stepped portion SPb, the contact CC has a low possibility of contacting with the columnar portion HRb. Therefore, the columnar portion HRb made of, for example, an insulator can be disposed above the lower stacked body LMa, that is, in the layer to which the upper stacked body LMb belongs, instead of the columnar portion HRa.

The semiconductor memory device 2 of the second embodiment includes a plurality of columnar portions HRb extending in the stacking direction through the upper position of the lower stepped portion Spa, and the upper stepped portion SPb, and the lower end portions of the plurality of columnar portions HRb are connected to the respective upper end portions of the plurality of columnar portions HRa.

As described above, disposing the columnar portion HRb having a simpler structure in the layer to which the upper stacked body LMb belongs allows the manufacturing load of the semiconductor memory device 2 to be reduced and the manufacturing cost to be reduced.

The semiconductor memory device 2 of the second embodiment otherwise has the same effect as the semiconductor memory device 1 of the first embodiment described above.

In the second embodiment described above, it has been assumed that the columnar portion HRb is disposed in the layer to which the upper stacked body LMb belongs. However, a columnar portion having the same configuration as that of the columnar portion HR of the first embodiment described above may be disposed in the layer to which the upper stacked body LMb belongs.

In the second embodiment described above, it has been assumed that the semiconductor memory device 2 is of a two-tier type including the upper stacked body LMb and the lower stacked body LMa. However, the number of tiers may be arbitrary, for example, three tiers or more. A multi-tier type semiconductor memory device such as the semiconductor memory device 2 is manufactured by forming each of the stacked body LMs, the stepped portion SP, the pillar PL, and the columnar portion HR separately for each tier, for example.

In other words, each time one tier of the stacked body LMs is formed, the stepped portion SP, the pillar PL, and the columnar portion HR are formed in the stacked body LMs. For example, a columnar portion HRb having a simpler structure may be formed in the stacked body LMs belonging to a relatively upper layer.

After all the tiers are formed, slits ST penetrating the stacked body LMs of each tier are formed to perform a replacement process, and a plurality of contacts CC connected to the respective word lines WL is formed in the stepped portion of each tier.

Adopting such a manufacturing method facilitates further increase in the number of stacked word lines WL in a multi-tier type semiconductor memory device.

### OTHER EMBODIMENTS

Other embodiments will be described below.

In the first and second embodiments and the modification described above, it has been assumed that the columnar portions HR and HRa include a semiconductor layer 31 as a core material. However, in the plasma etching treatment, another material may be used as the core material of the columnar portion, as long as the material provides high selectivity to the insulating layers 52 and 51 and the like. As an example, the core material of the columnar body as the first pillar may be a conductive layer as a second conductive layer such as a tungsten layer.

In the first and second embodiments and the modification described above, it has been assumed that the stepped region SR including the stepped portion SP is disposed at the end portion of the stacked body LM in the X direction. However, for example, a stepped region including a stepped portion formed by digging down the stacked body in a cone shape may be disposed at a predetermined position within the stacked body.

In the first and second embodiments and the modification described above, it has been assumed that a peripheral circuit contributing to the operation of the memory cell MC is disposed on the substrate SB around the stacked body LM. However, a stacked body may be disposed above a peripheral circuit disposed on a substrate including a transistor.

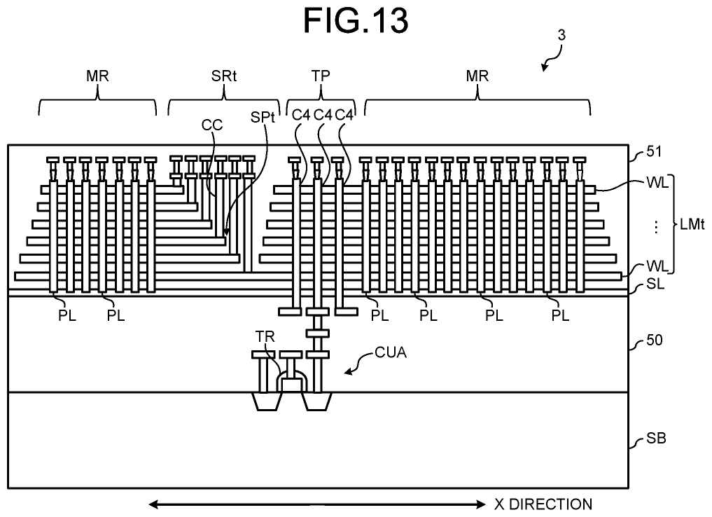

FIG. 13 illustrates an example of a semiconductor memory device 3 in which a stepped region SRt is disposed inside a stacked body LMt and a peripheral circuit CUA is provided below the stacked body LMt.

FIG. 13 is a cross-sectional view along the X direction illustrating a schematic configuration of the semiconductor memory device 3 according to another embodiment. In FIG. 13, however, hatching is omitted in consideration of the easiness of viewing the drawing. In FIG. 13, the insulating layer OL and some of the upper layer wiring of the stacked body LMt are omitted.

As illustrated in FIG. 13, the semiconductor memory device 3 includes the peripheral circuit CUA and the stacked body LMt on the substrate SB.

The peripheral circuit CUA includes a transistor TR disposed on the substrate SB, wiring on the upper layer of the transistor TR, and the like, and is covered with an insulating layer 50. On the insulating layer 50, a source line SL is disposed which is, for example, a conductive polysilicon layer. On the source line SL, the stacked body LMt is disposed in which a plurality of word lines WL is stacked via an insulating layer not illustrated in the figure. The stacked body LMt is covered with an insulating layer 51.

In the stacked body LMt, a plurality of memory regions MR, a stepped region SRt, and a through contact region TP are disposed in line with each other in the X direction. The plurality of memory regions MR in which the plurality of pillars PL is each disposed is disposed apart from the stepped region SRt and the through contact region TP in the X direction with the stepped region SRt and the through contact region TP interposed therebetween.

The stepped region SRt includes a stepped portion SPt in which a plurality of word lines WL is dug down in a cone shape in the stacking direction. The stepped portion SPt is descended from the memory region MR side toward the through contact region TP side, for example.

Each step of the stepped portion SPt is constituted of word lines WL in each layer. The word lines WL in each layer maintain electrical conduction on both sides of the stepped region SRt in the X direction through a region outside the stepped portion SPt in the Y direction. The contacts CC for connecting the word lines WL in each layer and the upper layer wiring are each disposed in terrace portions of respective steps of the stepped portions SPt. The above-described columnar portions HR (not illustrated) are disposed on the terrace portions of the respective steps of the stepped portions SPt.

The through contact region TP is disposed on one side of the stepped region SRt in the X direction. A through contact C4 penetrating the stacked body LMt is disposed in the through contact region TP. The through contact C4 connects the peripheral circuit CUA disposed on the lower substrate SB and the upper layer wiring connected to the contact CC of the stepped portion SPt. Various voltages applied from the contact CC to the memory cell are controlled by the peripheral circuit CUA via, for example, the through contact C4 and the upper layer wiring.

Alternatively, the peripheral circuit may be disposed above the stacked body. In this case, a semiconductor memory device having such a disposition is obtained by forming a stacked body including various configurations on a substrate different from a peripheral circuit, and bonding the substrate on which the peripheral circuit is formed and the substrate on which the stacked body is formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which a plurality of first conductive layers and a plurality of first insulating layers are alternately stacked one by one, and includes a stepped portion in which the plurality of first conductive layers being processed in a stepped manner;
a first pillar disposed in the stepped portion, the first pillar extending in a stacking direction of the stacked body;
a second pillar extending in the stacking direction within the stacked body at a position apart from the stepped portion in a first direction intersecting the stacking direction, the second pillar forming a memory cell at each intersection with at least a part of the plurality of first conductive layers; and
a contact disposed in the stepped portion, the contact being connected to one of the plurality of first conductive layers,
wherein the first pillar has:
a semiconductor layer or a second conductive layer extending in the stacking direction and serving as a core material of the first pillar; and
a second insulating layer covering a side wall of the semiconductor layer or the second conductive layer and serving as a liner layer of the first pillar.

2. The semiconductor memory device according to claim 1, wherein
the contact has:
a third conductive layer extending in the stacking direction; and
a third insulating layer covering a side wall of the third conductive layer, and
a layer thickness of the third insulating layer in a direction along each layer of the stacked body is larger than or equal to a layer thickness of the second insulating layer in the direction along each layer of the stacked body.

3. The semiconductor memory device according to claim 2, wherein
a part or a whole of at least one of the first pillar and the contact is intersected obliquely to an other, and
a lower end portion of the contact is in contact with a side face of the first pillar.

4. The semiconductor memory device according to claim 3, wherein
at least the third insulating layer is interposed between the core material of the first pillar and the third conductive layer of the contact.

5. The semiconductor memory device according to claim 4, wherein
the second insulating layer is not interposed between the core material of the first pillar and the third conductive layer of the contact in at least a portion in the stacking direction.

6. The semiconductor memory device according to claim 4, wherein
the core material of the first pillar is in contact with the third insulating layer of the contact in at least a portion in the stacking direction.

7. The semiconductor memory device according to claim 2, wherein
the first pillar includes a plurality of first pillars disposed dispersedly in the stepped portion, and
the contact includes a plurality of contacts connected to each of the plurality of first conductive layers.

8. The semiconductor memory device according to claim 2, wherein
the second pillar includes a plurality of second pillars disposed dispersedly in a memory region apart from the stepped portion in the first direction, and
the first pillar includes a plurality of first pillars, a part of the plurality of first pillars being disposed dispersedly in the stepped portion, an other part of the plurality of first pillars being disposed dispersedly in the memory region.

9. The semiconductor memory device according to claim 1, further comprising:
an upper stacked body disposed on the stacked body, the upper stacked body in which the plurality of first conductive layers and the plurality of first insulating layers are alternately stacked one by one and includes an upper stepped portion, the upper stepped portion being ascended toward a region where the second pillar is disposed, continuously from an uppermost step of the stepped portion; and
a plurality of third pillars extending through an upper position of the stepped portion and the upper stepped portion in the stacking direction, wherein
the first pillar includes a plurality of first pillars each disposed at positions within the stacked body overlapping the upper stepped portion in the stacking direction and at the stepped portion, and
each lower end portion of the plurality of third pillars is connected to an upper end portion of the plurality of first pillars.

10. The semiconductor memory device according to claim 9, wherein each of the plurality of third pillars is an insulator.

11. A method of manufacturing a semiconductor memory device, the method comprising:
forming a stacked body in which a plurality of first conductive layers and a plurality of first insulating layers are alternately stacked one by one, and includes a stepped portion in which the plurality of first conductive layers being processed in a stepped manner;
forming a first pillar in the stepped portion, the first pillar having: a semiconductor layer or a second conductive layer extending in a stacking direction of the stacked body and serving as a core material; and a second insulating layer serving as a liner layer covering a side wall of the semiconductor layer or the second conductive layer;
forming a second pillar extending in the stacking direction within the stacked body at a position apart from the stepped portion in a first direction intersecting the stacking direction, the second pillar forming a memory cell at each intersection with at least a part of the plurality of first conductive layers; and
forming a contact in the stepped portion, the contact having a third conductive layer extending in the stacking direction and a third insulating layer covering a side wall of the third conductive layer, the contact being connected to one of the plurality of first conductive layers.

12. The method of manufacturing a semiconductor memory device according to claim 11, wherein forming the contact includes:
forming the third insulating layer such that a layer thickness of the third insulating layer in a direction along each layer of the stacked body is larger than or equal to a layer thickness of the second insulating layer in the direction along each layer of the stacked body.

13. The method of manufacturing a semiconductor memory device according to claim 11, wherein forming the contact includes:
forming a contact hole extending in the stacking direction in the stepped portion;
forming the third insulating layer on a side wall of the contact hole; and
filling the third conductive layer inside the third insulating layer.

14. The method of manufacturing a semiconductor memory device according to claim 13, wherein forming the contact includes:
filling the third conductive layer within the contact hole by interposing at least a third insulating layer between the third conductive layer and the core material of the first pillar when a part or a whole of at least one of the first pillar and the contact hole is intersected obliquely to an other and a lower end portion of the contact hole comes into contact with a side face of the first pillar.

15. The method of manufacturing a semiconductor memory device according to claim 13, wherein forming the contact includes:
etch-stopping a lower end portion of the contact hole by at least the core material of the first pillar when a part or a whole of at least one of the first pillar and the contact hole is intersected obliquely to an other and a lower end portion of the contact hole comes into contact with a side face of the first pillar.

16. The method of manufacturing a semiconductor memory device according to claim 15, wherein forming the contact includes:
covering the core material with the third insulating layer when the lower end portion of the contact hole comes into contact with the side face of the first pillar and the core material of the first pillar is exposed.

17. The method of manufacturing a semiconductor memory device according to claim 11, wherein
forming the first pillar includes dispersedly forming a plurality of first pillars in the stepped portion, and
forming the contact includes forming a plurality of contacts connected to each of the plurality of first conductive layers on each step of the stepped portion.

18. The method of manufacturing a semiconductor memory device according to claim 17, wherein forming the plurality of contacts includes:
collectively forming a plurality of contact holes extending in the stacking direction in the stepped portion.

19. The method of manufacturing a semiconductor memory device according to claim 11, wherein
forming the second pillar includes dispersedly forming a plurality of second pillars in a memory region apart from the stepped portion in the first direction, and
forming the first pillar includes dispersedly forming a plurality of first pillars in the stepped portion and the memory region.

20. The method of manufacturing a semiconductor memory device according to claim 11, the method further comprising:
forming an upper stacked body in which the plurality of first conductive layers and the plurality of first insulating layers are alternately stacked one by one, on the stacked body; and
forming an upper stepped portion in the upper stacked body, the upper stepped portion being ascended toward a region where the second pillar is disposed, continuously from an uppermost step of the stepped portion,
wherein forming the first pillar includes:
forming a plurality of first pillars each at positions within the stacked body overlapping the upper stepped portion in the stacking direction and at the stepped portion, and
the method further comprises:
forming a plurality of third pillars, which is an insulator, extending in the stacking direction at an upper position of the stepped portion and at the upper stepped portion; and connecting each lower end portion of the plurality of third pillars to an upper end portion of the plurality of first pillars.
